(19) United States
(12) Patent Application Publication
(10) Pub. No.: US 2025/0125252 A1
(43) Pub. Date: Apr. 17, 2025

(54) SEMICONDUCTOR DEVICE AND MANUFACTURING METHOD THEREOF

(71) Applicant: UNITED MICROELECTRONICS CORP., Hsin-Chu City (TW)

(72) Inventors: Chin-Chia Yang, Tainan City (TW); Da-Jun Lin, Kaohsiung City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/516,868

(22) Filed: Nov. 21, 2023

(30) Foreign Application Priority Data
Oct. 12, 2023 (CN) 202311321412.0

(51) Int. Cl. H01L 23/522; H01L 21/768

(52) U.S. Cl. CPC H01L 23/5226; H01L 21/76805; H01L 21/7684

(57) ABSTRACT

A semiconductor device includes a device layer, an interlayer dielectric layer disposed above the device layer, a first interconnection structure, a second interconnection structure, and a first dielectric layer. The interlayer dielectric layer includes a first portion and a second portion disposed above a first device region and a second device region, respectively. A top surface of the first portion is lower than a top surface of the second portion in a vertical direction. The first interconnection structure includes first conductive lines partly located in the first portion. The second interconnection structure includes second conductive lines located in the second portion. The first dielectric layer is disposed on the first portion, a part of the first dielectric layer is sandwiched between two adjacent first conductive lines, and a bottom surface of the first dielectric layer is lower than the top surface of the second portion in the vertical direction.

### BACKGROUND OF THE INVENTION

### 1. Field of the Invention

The present invention relates to a semiconductor device and a manufacturing method thereof, and more particularly, to a semiconductor device including an interconnection structure and a manufacturing method thereof.

### 2. Description of the Prior Art

In the integrated circuits, transistors may be different from one another in structure for different operation voltages. For example, the transistors for relatively low operation voltage may be applied in core devices, input/output (I/O) devices, and so on. The transistors capable of high voltage processing may be applied in high operation voltage environment such as CPU power supply, power management system, AC/DC converter, and high-power or power amplifier.

However, transistors designed for different operation voltages and interconnections structures located corresponding to the transistors are formed on the same wafer or chip generally, and the structural design considerations will be different because of different operation voltages. Therefore, how to improve the operation performance of different device regions and/or integrate manufacturing process steps for different device regions through the design of structure and/or the design of the manufacturing process is a continuous issue for those in the related fields.

### SUMMARY OF THE INVENTION

A semiconductor device and a manufacturing method thereof are provided in the present invention. A surface height difference of an interlayer dielectric layer corresponding to different device regions is applied for forming an additional dielectric layer, so as to meet the characteristic requirements of interconnection structures located corresponding to different device regions.

According to an embodiment of the present invention, a semiconductor device is provided. The semiconductor device includes a device layer, an interlayer dielectric layer, a first interconnection structure, a second interconnection structure, and a first dielectric layer. The device layer includes a first device region and a second device region. The interlayer dielectric layer is disposed above the device layer, and the interlayer dielectric layer includes a first portion and a second portion. The first portion is disposed above the first device region, the second portion is disposed above the second device region, and a top surface of the first portion is lower than a top surface of the second portion in a vertical direction. The first interconnection structure is disposed corresponding to the first device region, the first interconnection structure includes first conductive lines, and each of the first conductive lines is partly located in the first portion of the interlayer dielectric layer. The second interconnection structure is disposed corresponding to the second device region, and the second interconnection structure includes second conductive lines located in the second portion of the interlayer dielectric layer. The first dielectric layer is disposed on the first portion of the interlayer dielectric layer, a part of the first dielectric layer is sandwiched between two of the first conductive lines adjacent to each other, and a bottom surface of the first dielectric layer is lower than the top surface of the second portion of the interlayer dielectric layer in the vertical direction.

According to an embodiment of the present invention, a manufacturing method of a semiconductor device is provided. The manufacturing method includes the following steps. A device layer is provided, and the device layer includes a first device region and a second device region. An interlayer dielectric layer is formed above the device layer, and the interlayer dielectric layer includes a first portion and a second portion. The first portion is disposed above the first device region, the second portion is disposed above the second device region, and a top surface of the first portion is lower than a top surface of the second portion in a vertical direction. A first dielectric layer is formed on the first portion of the interlayer dielectric layer. First conductive lines are formed, each of the first conductive lines is partly located in the first portion of the interlayer dielectric layer, and the first conductive lines are a portion of a first interconnection structure located corresponding to the first device region. Second conductive lines are formed in the second portion of the interlayer dielectric layer, and the second conductive lines are a portion of a second interconnection structure located corresponding to the second device region. A part of the first dielectric layer is sandwiched between two of the first conductive lines adjacent to each other, and a bottom surface of the first dielectric layer is lower than the top surface of the second portion of the interlayer dielectric layer in the vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor device according to a first embodiment of the present invention.

FIGS. 2-7 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, and FIG. 7 is a schematic drawing in a step subsequent to FIG. 6.

FIG. 8 is a schematic drawing illustrating a semiconductor device according to a second embodiment of the present invention.

FIG. 9 is a schematic drawing illustrating a semiconductor device according to a third embodiment of the present invention.

FIG. 10 is a schematic drawing illustrating a device layer in the semiconductor device according to an embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

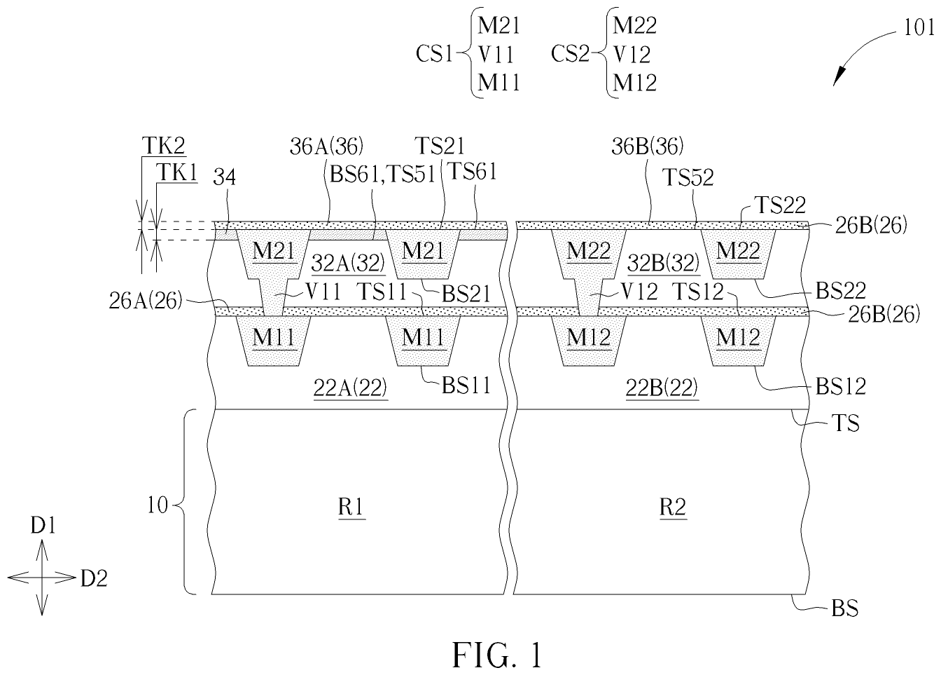

Please refer to FIG. 1. FIG. 1 is a schematic drawing illustrating a semiconductor device 101 according to a first embodiment of the present invention. As shown in FIG. 1, the semiconductor device 101 includes a device layer 10, an interlayer dielectric layer 32, a first interconnection structure CS1, a second interconnection structure CS2, and a first dielectric layer (such as a dielectric layer 34). The device layer 20 includes a first device region R1 and a second device region R2, and the interlayer dielectric layer 32 is disposed above the device layer 10. The interlayer dielectric layer 32 includes a first portion 32A and a second portion 32B. The first portion 32A is disposed above the first device region R1, the second portion 32B is disposed above the second device region R2, and a top surface TS51 of the first portion 32A is lower than a top surface TS52 of the second portion 32B in a vertical direction D1. The first interconnection structure CS1 is disposed corresponding to the first device region R1, the first interconnection structure CS1 includes first conductive lines (such as conductive lines M21), and each of the conductive lines M21 is partly located in the first portion 32A of the interlayer dielectric layer 32. The second interconnection structure CS2 is disposed corresponding to the second device region R2, and the second interconnection structure CS2 includes second conductive lines (such as conductive lines M22) located in the second portion 32B of the interlayer dielectric layer 32. The dielectric layer 34 is disposed on the first portion 32A of the interlayer dielectric layer 32, a part of the dielectric layer 34 is sandwiched between two of the conductive lines M21 adjacent to each other, and a bottom surface BS61 of the dielectric layer 34 is lower than the top surface TS52 of the second portion 32B of the interlayer dielectric layer 32 in the vertical direction D1. By the design where the top surface of the interlayer dielectric layer 32 located above the first device region R1 is lower than the top surface of the interlayer dielectric layer 32 located above the second device region R2, the dielectric layer 34 may be disposed on the first portion 32A of the interlayer dielectric layer 32 and be partly sandwiched between the conductive lines M21 adjacent to each other for improving the reliability of the first interconnection structure CS1 and the dielectric materials adjacent to the first interconnection structure CS1. For example, characteristics such as time dependent dielectric breakdown (TDDB) and voltage ramp dielectric breakdown (VRDB) may be improved accordingly, but not limited thereto.

In some embodiments, the vertical direction D1 described above may be regarded as a thickness direction of the device layer and/or a thickness direction of a semiconductor substrate (not illustrated in FIG. 1) in the device layer 10. The device layer 10 may have a top surface TS and a bottom surface BS opposite to the top surface TS in the vertical direction D1, and the interlayer dielectric layer 32, the first interconnection structure CS1, the second interconnection structure CS2, and the dielectric layer 34 described above may be disposed at the side of the top surface TS of the device layer 10. Horizontal directions substantially orthogonal to the vertical direction D1 (such as a horizontal direction D2 and other directions orthogonal to the vertical direction D1) may be substantially parallel with the top surface TS and/or the bottom surface BS of the device layer 10, but not limited thereto. In this description, a distance between the bottom surface BS of the device layer 10 and a relatively higher location and/or a relatively higher part in the vertical direction D1 may be greater than a distance between the bottom surface BS of the device layer 10 and a relatively lower location and/or a relatively lower part in the vertical direction D1. The bottom or a lower portion of each component may be closer to the bottom surface BS of the device layer 10 in the vertical direction D1 than the top or upper portion of this component. Another component disposed above a specific component may be regarded as being relatively far from the bottom surface BS of the device layer 10 in the vertical direction D1, and another component disposed under a specific component may be regarded as being relatively close to the bottom surface BS of the device layer 10 in the vertical direction D1. Additionally, in this description, a top surface of a specific component may include the topmost surface of this component in the vertical direction D1, and a bottom surface of a specific component may include the bottommost surface of this component in the vertical direction D1, but not limited thereto. In this description, the condition that a certain component is disposed between two other components in a specific direction may include a condition that the certain component is sandwiched between the two other components in the specific direction. In addition, in this description, a thickness of a specific component may include but is not limited to a thickness of this component in the vertical direction D1, unless an addition description is accompanied.

In some embodiments, the device layer 10 may include a semiconductor substrate and active components and/or passive components disposed on the semiconductor substrate, such as transistors, diodes, capacitors, resistors, and so forth, and the first device region R1 and the second device region R2 may respectively include different components, such as transistor structures with different operation voltages, but not limited thereto. For example, the first device region R1 may be a high voltage device region and include high voltage transistor devices, the second device region R2 may be a low voltage device region and include low voltage transistor devices, and the first interconnection structure CS1 and the second interconnection structure CS2 may be interconnection structures disposed corresponding to and electrically connected with the high voltage transistor device and the low voltage transistor device, respectively. In some embodiments, the semiconductor device 101 may further include an interlayer dielectric layer 22, a dielectric layer 26, and a second dielectric layer (such as a dielectric layer 36). The interlayer dielectric layer 22 may be disposed between the device layer 10 and the interlayer dielectric layer 32, the dielectric layer 26 may be disposed between the interlayer dielectric layer 22 and the interlayer dielectric layer 32, and the dielectric layer 36 may be disposed on each of the conductive lines M21, the dielectric layer 34, each of the conductive lines M22, and the second portion 32B of the interlayer dielectric layer 32. The interlayer dielectric layer 22 may include a first portion 22A disposed above the first device region R1 and a second portion 22B disposed above the second device region R2, the dielectric layer 26 may include a first portion 26A disposed above the first portion 22A of the interlayer dielectric layer 22 and a second portion 26B disposed above the second portion 22B of the interlayer dielectric layer 22, and the dielectric layer 36 may include a first portion 36A disposed above the first device region R1 and a second portion 36B disposed above the second device region R2.

In some embodiments, the first interconnection structure CS1 may further include a plurality of conductive lines M11 and at least one electrically conductive via structure V11, and the second interconnection structure CS2 may further include a plurality of conductive lines M12 and at least one electrically conductive via structure V12. The conductive lines M11 may be disposed in the first portion 22A of the interlayer dielectric layer 22, the electrically conductive via structure V11 may be disposed between the conductive line M11 and the conductive line M21 for electrically connecting the conductive line M11 and the conductive line M21, and the electrically conductive via structure V11 may be partly disposed in the first portion 32A of the interlayer dielectric layer 32 and penetrate through the first portion 26A of the dielectric layer 26 in the vertical direction D1. The conductive lines M12 may be disposed in the second portion 22B of the interlayer dielectric layer 22, the electrically conductive via structure V12 may be disposed between the conductive line M12 and the conductive line M22 for electrically connecting the conductive line M12 and the conductive line M22, and the electrically conductive via structure V12 may be partly disposed in the second portion 32B of the interlayer dielectric layer 32 and penetrate through the second portion 26B of the dielectric layer 26 in the vertical direction D1. In some embodiments, the conductive line and the electrically conductive via structure in the first interconnection structure CS1 and the second interconnection structure CS2 may include a barrier layer and a low electrically resistance material disposed on the barrier layer, the low electrically resistance material may include a material with relatively low electrical resistivity, such as copper, aluminum, tungsten, and so forth, and the barrier layer may include titanium nitride, tantalum nitride, or other suitable barrier materials, but not limited thereto.

In some embodiments, the interlayer dielectric layer 22 and the interlayer dielectric layer 32 may respectively include a single layer or multiple layers of dielectric materials, such as silicon oxide, fluorosilicate glass (FSG), a low dielectric constant (low-k) dielectric material, an ultra low dielectric constant (ULK) dielectric material, or other suitable dielectric materials. The low-k dielectric material and the ULK dielectric material described above may include dielectric materials with relatively low dielectric constant (such as dielectric constants lower than 2.9 and 2.7, respectively, but not limited thereto), such as benzocyclobutene (BCB), hydrogen silsesquioxane (HSQ), methyl silsesquioxane (MSQ), hydrogenated silicon oxycarbide (SiOC—H), and/or porous dielectric materials. In addition, the dielectric layer 26, the dielectric layer 34, and the dielectric layer 36 may respectively include nitrogen doped carbide (NDC), such as nitrogen doped silicon carbide, silicon nitride, silicon oxycarbide (SiOC), silicon oxycarbonitride (SiOCN), or other suitable dielectric materials. In some embodiments, the thickness of the interlayer dielectric layer 22 and the thickness of the interlayer dielectric layer 32 may be respectively greater than the thickness of the dielectric layer 26, the thickness of the dielectric layer 34, and the thickness of the dielectric layer 36, and the dielectric constant of the interlayer dielectric layer 22 and the interlayer dielectric layer 32 may be relatively low for improving some characteristics, such as RC delay and capacitance effect between the interconnection structures and/or between conductive lines in the interconnection structure. Therefore, the dielectric constant of the dielectric layer 26 and the dielectric constant of the dielectric layer 36 may be higher than the dielectric constant of the interlayer dielectric layer 22 and the dielectric constant of the interlayer dielectric layer 32.

In addition, a dielectric constant of the dielectric layer 34 partly disposed between the conductive lines M21 adjacent to each other in the horizontal direction (such as the horizontal direction D2) may be higher than the dielectric constant of the interlayer dielectric layer 32 and the dielectric constant of the interlayer dielectric layer 22 for improving the reliability of the dielectric material located between the conductive lines M21, such as improving TDDB and VRDB, but not limited thereto, especially when the first interconnection structure CS1 is electrically connected with the high voltage transistor and has to be used for transmitting high voltage signals. In some embodiments, when considering the negative influence generated by the high dielectric constant (such as making RC delay more seriously, but not limited thereto), the dielectric constant of the dielectric layer 34 may range from 4 to 6 preferably, i.e. the dielectric constant of the dielectric layer 34 may be greater than or equal to 4 and less than or equal to 6, but not limited thereto. In some embodiments, a material composition of the dielectric layer 34 may be different from or identical to a material composition of the dielectric layer 36. For example, when the dielectric layer 26 and the dielectric layer 36 are used as etching stop layers and/or have other material characteristic specifications, the material composition of the dielectric layer 36 may be different from the material composition of the dielectric layer 34, the dielectric constant of the dielectric layer 34 may be greater than the dielectric constant of the dielectric layer 36, and a thickness TK1 of the dielectric layer 34 may be greater than a thickness TK2 of the dielectric layer 36, but not limited thereto. In some embodiments, the thickness TK1 and the thickness TK2 may range from 50 angstroms to 750 angstroms. In some embodiments, the thickness of the dielectric layer 34 may be correspondingly reduced for reducing the negative influence of the dielectric layer 34 on the capacitance effect and/or RC delay between the conductive lines M21, and the thickness of the dielectric layer 34 may be less than or equal to the thickness of the dielectric layer 36 under this situation.

In some embodiments, the thickness of the first portion 22A of the interlayer dielectric layer 22 may be substantially equal to that of the second portion 22B of the interlayer dielectric layer 22, and the conductive lines M11 and the conductive lines M12 may be formed concurrently by the same process and may be regarded as electrically conductive layers located at the same level, such as patterned metallic electrically conductive layers located at the same level and/or located at the same position in the vertical direction. Therefore, a bottom surface BS11 of each of the conductive lines M11 and a bottom surface BS12 of each of the conductive lines M12 may be substantially coplanar, and a top surface TS11 of each of the conductive lines M11 and a top surface TS12 of each of the conductive lines M12 may be substantially coplanar, but not limited thereto. In addition, a thickness of the first portion 26A of the dielectric layer 26 may be substantially equal to a thickness of the second portion 26B of the dielectric layer 26, and a thickness of the first portion 32A of the interlayer dielectric layer 32 may be less than a thickness of the second portion 32B of the interlayer dielectric layer 32. In some embodiments, the conductive lines M21 and the conductive lines M22 may be formed concurrently by the same process and may be regarded as electrically conductive layers located at the same level, such as patterned metallic electrically conductive layers located at the same level and/or located at the same position in the vertical direction. Therefore, a bottom surface BS21 of each of the conductive lines M21 and a bottom surface BS22 of each of the conductive lines M22 may be substantially coplanar, and a top surface TS21 of each of the conductive lines M21 and a top surface TS22 of each of the conductive lines M22 may be substantially coplanar, but not limited thereto.

In some embodiments, the bottom surface BS61 of the dielectric layer 34 may directly contact the top surface TS51 of the first portion 32A of the interlayer dielectric layer 32, and the dielectric layer 34 may directly contact the sidewall of the conductive line M21 and the first portion 36A of the dielectric layer 36. Additionally, the bottom surface BS61 of the dielectric layer 34 and the top surface TS51 of the first portion 32A of the interlayer dielectric layer 32 may be higher than the bottom surface BS21 of each of the conductive lines M21 and the bottom surface BS22 of each of the conductive lines M22 in the vertical direction D1, and the bottom surface BS61 of the dielectric layer 34 and the top surface TS51 of the first portion 32A of the interlayer dielectric layer 32 may be lower than the top surface TS21 of each of the conductive lines M21 and the top surface TS22 of each of the conductive lines M22 in the vertical direction D1. Therefore, a part of the dielectric layer 34 and a part of the first portion 32A of the interlayer dielectric layer 32 may be sandwiched between the conductive lines M21 located adjacent to each other in the horizontal direction, and a thickness of the interlayer dielectric layer 32 sandwiched between the conductive lines M21 located adjacent to each other in the horizontal direction may be greater than a thickness of the dielectric layer 34 sandwiched between the conductive lines M21 located adjacent to each other in the horizontal direction. Additionally, in some embodiments, the top surface TS21 of each of the conductive lines M21 and the top surface TS61 of the dielectric layer 34 may be substantially coplanar, and the top surface TS22 of each of the conductive lines M22 and the top surface TS52 of the second portion 32B of the interlayer dielectric layer 32 may be substantially coplanar, but not limited thereto. In some embodiments, the dielectric layer 36 may directly contact each of the conductive lines M21, the dielectric layer 34, each of the conductive lines M22, and the second portion 32B of the interlayer dielectric layer 32, and a thickness of the first portion 36A of the dielectric layer 36 may be substantially equal to a thickness of the second portion 36B of the dielectric layer 36.

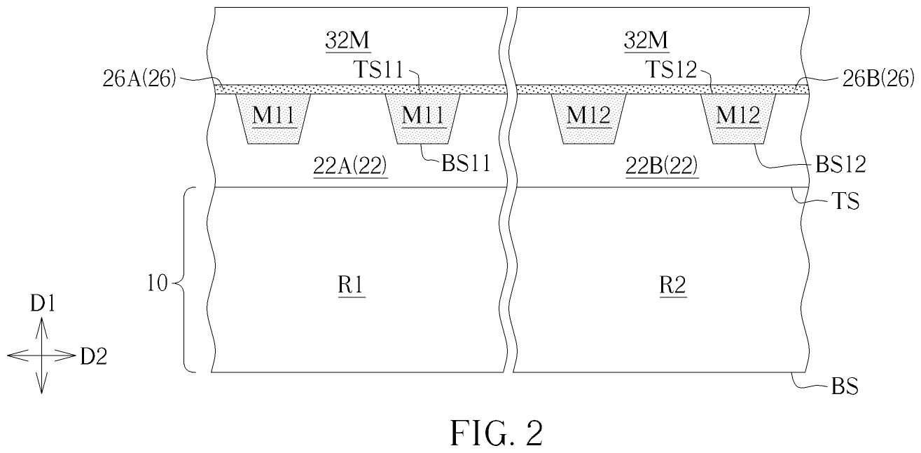

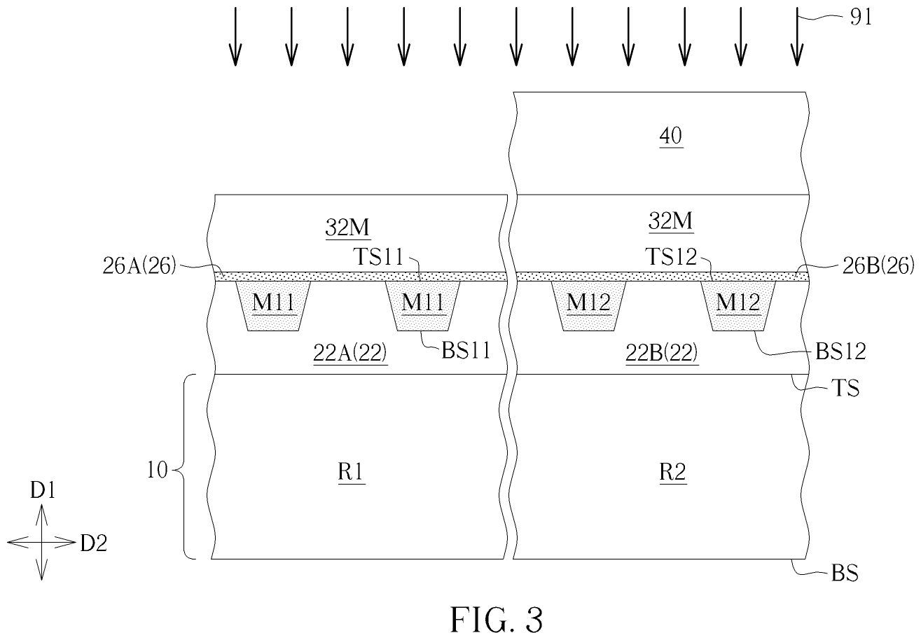

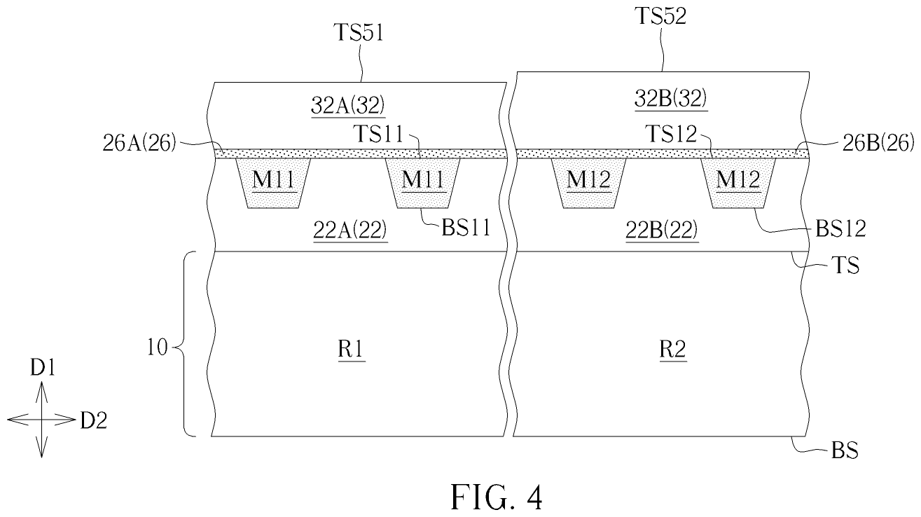

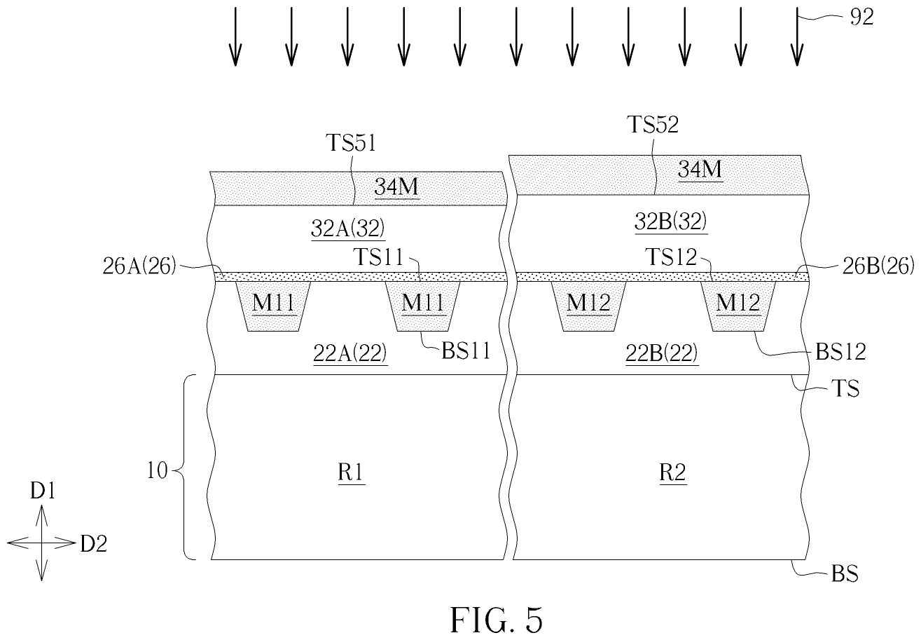

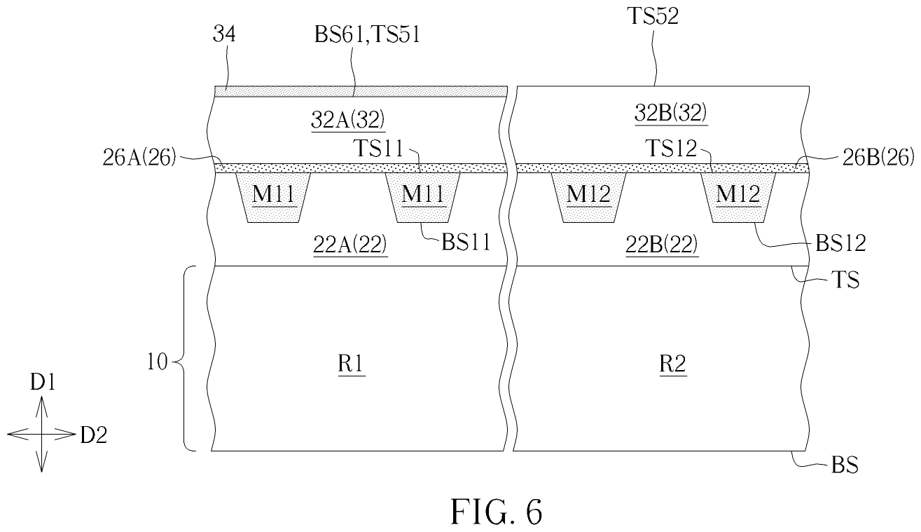

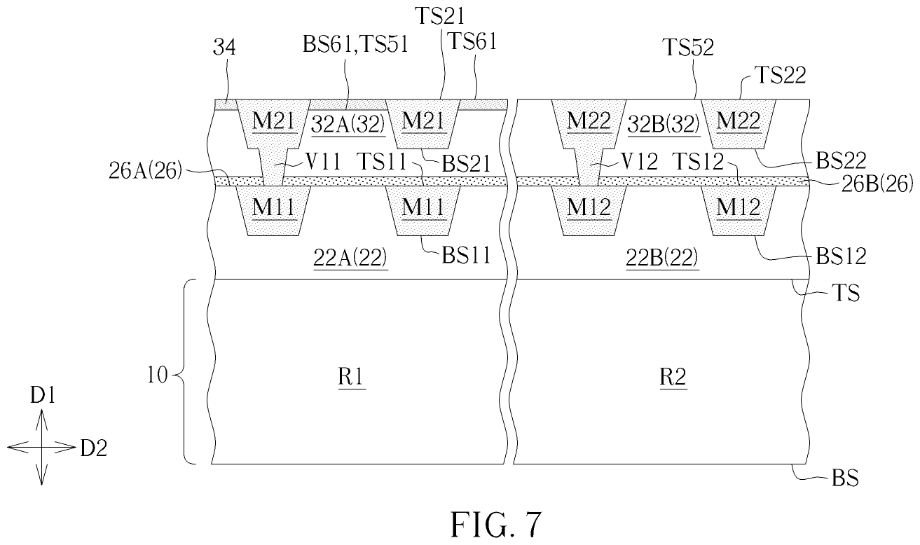

Please refer to FIGS. 1-7. FIGS. 2-7 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, and FIG. 7 is a schematic drawing in a step subsequent to FIG. 6. In some embodiments, FIG. 1 may be regarded as a schematic drawing in a step subsequent to FIG. 7, but not limited thereto. As shown in FIG. 1, the manufacturing method in this embodiment may include the following steps. The device layer 10 is provided, and the device layer 10 includes the first device region R1 and the second device region R2. The interlayer dielectric layer 32 is formed above the device layer 10, and the interlayer dielectric layer 32 includes the first portion 32A and the second portion 32B. The first portion 32A is disposed above the first device region R1, the second portion 32B is disposed above the second device region R2, and the top surface TS51 of the first portion 32A is lower than the top surface TS52 of the second portion 32B in the vertical direction D1. The first dielectric layer (such as the dielectric layer 34) is formed on the first portion 32A of the interlayer dielectric layer 32. The first conductive lines (such as the conductive lines M21) are formed, each of the conductive lines M21 is partly located in the first portion 32A of the interlayer dielectric layer 32, and the conductive lines M21 are a portion of the first interconnection structure CS1 located corresponding to the first device region R2. The second conductive lines (such as the conductive lines M22) are formed in the second portion 32B of the interlayer dielectric layer 32, and the conductive lines M22 are a portion of the second interconnection structure CS2 located corresponding to the second device region R2. A part of the dielectric layer 34 is sandwiched between two of the conductive lines M21 adjacent to each other, and the bottom surface BS61 of the dielectric layer 34 is lower than the top surface TS52 of the second portion 32B of the interlayer dielectric layer 32 in the vertical direction D1.

Specifically, the manufacturing method in this embodiment may include but is not limited to the following steps. As shown in FIG. 2, after the interlayer dielectric layer 22, the conductive lines M11, the conductive lines M12, and the dielectric layer 26 are formed on the device layer 10, an interlayer dielectric material 32M may be formed on the dielectric layer 26. A method of forming the conductive lines M11 and the conductive lines M12 may include forming trenches in the interlayer dielectric layer 22, forming an electrically conductive material partly in the trenches and partly outside the trenches, and performing a planarization process to the electrically conductive material for removing the electrically conductive material located outside the trenches and forming the conductive lines M11 and the conductive lines M12 in the trenches accordingly, but not limited thereto. The interlayer dielectric material 32M may be formed above the device layer 10, and the interlayer dielectric material 32M may be partly located above the first device region R1 and partly located above the second device region R2. A thickness of the interlayer dielectric material 32M formed above the first device region R1 may be substantially equal to a thickness of the interlayer dielectric material 32M formed above the second device region R2. Subsequently, an etching process 91 may be performed to the interlayer dielectric material 32M located above the first device region R1. Before the etching process 91, a patterned mask layer 40 may be formed on the interlayer dielectric material 32M located above the second device region R2. The patterned mask layer 40 may be used as an etching mask in the etching process 91 for covering the interlayer dielectric material 32M located above the second device region R2 during the etching process 91, and the patterned mask layer 40 may include photoresist or other suitable mask materials.

As shown in FIG. 3 and FIG. 4, at least a part (such as an upper part) of the interlayer dielectric material 32M located above the first device region R1 may be etched to be the first portion 32A of the interlayer dielectric layer 32 by the etching process 91, and the interlayer dielectric material 32M located above the second device region R2 becomes the second portion 32B of the interlayer dielectric layer 32 after the etching process 91. In other words, the etching process 91 may be regarded as an etching back process for reducing the thickness of the interlayer dielectric material 32M located above the first device region and forming the first portion 32A of the interlayer dielectric layer 32, and the first portion 32A is relatively thin and the top surface of the first portion 32A is relatively low. It is worth noting that, in this invention, the method of forming the interlayer dielectric layer 32 may include but is not limited to the steps in FIGS. 2-4 described above, and the interlayer dielectric layer 32 illustrated in FIG. 4 may also be formed by other suitable approaches according to some design considerations.

Subsequently, as shown in FIG. 5, a dielectric material 34M may be formed above the interlayer dielectric layer 32, the dielectric material 34M may be partly located above the first portion 32A of the interlayer dielectric layer 32 and partly located on the second portion 32B of the interlayer dielectric layer 32, and a thickness of the dielectric material 34M located on the first portion 32A may be substantially equal to a thickness of the dielectric material 34M located on the second portion 32B. As shown in FIG. 5 and FIG. 6, a planarization process 92 is then performed to the dielectric material 34M, the dielectric material 34M located on the second portion 32B of the interlayer dielectric layer 32 may be removed by the planarization process 92 (such as being completely removed by the planarization process 92), and the dielectric material 34M remaining on the first portion 32A of the interlayer dielectric layer 32 after the planarization process 92 becomes the dielectric layer 34 described above. The planarization process 92 may include a chemical mechanical polishing (CMP) process, an etching back process, or other suitable planarization approaches. It is worth noting that, in this invention, a method of forming the dielectric layer 34 may include but is not limited to the steps in FIG. 5 and FIG. 6 described above, and the dielectric layer 34 illustrated in FIG. 6 may also be formed by other suitable approaches according to some design considerations.

As shown in FIG. 7, after the step of forming the dielectric layer 34, the conductive lines M21, the conductive lines M22, the electrically conductive via structure V11, and the electrically conductive via structure V12 described above may be formed. In some embodiments, the conductive lines M21, the conductive lines M22, the electrically conductive via structure V11, and the electrically conductive via structure V12 may be formed concurrently by the same process, but not limited thereto. For example, a trench penetrating through the dielectric layer 34 in the vertical direction D1 and partly located in the first portion 32A of the interlayer dielectric layer 32 and an opening penetrating through the first portion 26A of the dielectric layer 26 in the vertical direction D1 and partly located in the first portion 32A of the interlayer dielectric layer 32 may be formed above the first device region R1, and a trench located in the second portion 32B of the interlayer dielectric layer 32 and an opening penetrating through the second portion 26B of the dielectric layer 26 in the vertical direction D1 and partly located in the second portion 32B of the interlayer dielectric layer 32 may be formed above the second device region R2. Subsequently, an electrically conductive material may be formed, the trenches and the openings described above may be filled with the electrically conductive material, and the electrically conductive material may be partly located outside the trenches and the openings. A planarization process may be performed to the electrically conductive material for removing the electrically conductive material located outside the trenches and the openings so as to form the conductive lines M21 and the conductive lines M22 in the trenches and form the electrically conductive via structure V11 and the electrically conductive via structure V12 in the openings, but not limited thereto. In some embodiments, the electrically conductive via structures and the conductive lines may be formed by different manufacturing methods, respectively, according to some design considerations. It is worth noting that, because of the influence of the planarization process applied in the step of forming the dielectric layer 34 and/or the influence of the planarization process applied in the step of forming the conductive lines M21 and the conductive lines M22, the top surface TS21 of the conductive line M21, the top surface TS61 of the dielectric layer 34, the top surface TS22 of the conductive line M22, and the top surface TS52 of the second portion 32B of the interlayer dielectric layer 32 may be substantially coplanar, but not limited thereto. As shown in FIG. 7 and FIG. 1, the dielectric layer 36 described above may then be formed on the conductive lines M21, the dielectric layer 34, the conductive lines M22, and the second portion 32B of the interlayer dielectric layer 32.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

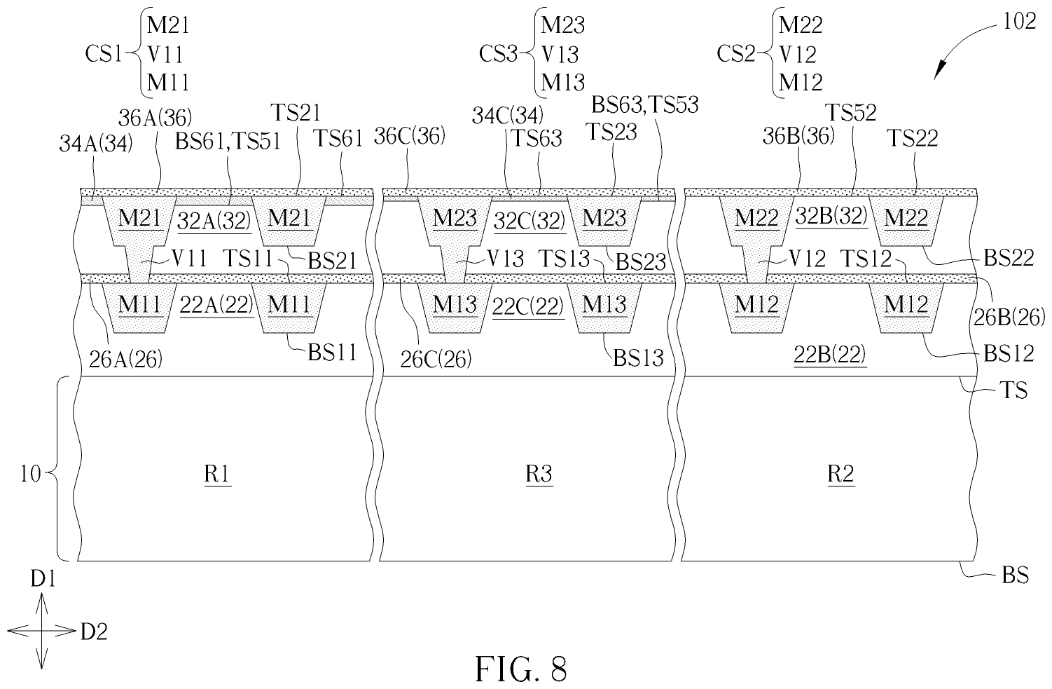

Please refer to FIG. 8. FIG. 8 is a schematic drawing illustrating a semiconductor device 102 according to a second embodiment of the present invention. As shown in FIG. 8, in the semiconductor device 102, the device layer 10 may further includes a third device region R3, the interlayer dielectric layer 22, the dielectric layer 26, the interlayer dielectric layer 32, and the dielectric layer 36 may further include a third portion 22C, a third portion 26C, a third portion 32C, and a third portion 36C, respectively, disposed above the third device region R3, and the dielectric layer 34 may further include a second portion 34C disposed above the third device region R3. A top surface TS53 of the third portion 32C of the interlayer dielectric layer 32 may be lower than the top surface TS52 of the second portion 32B and higher than the top surface TS51 of the first portion 32A in the vertical direction D1. In addition, the semiconductor device 102 may further include a third interconnection structure CS3 disposed corresponding to the third device region R3. The third interconnection structure CS may be disposed above the third device region R3 in the vertical direction D1 and include third conductive lines (such as conductive lines M23), and each of the conductive lines M23 is partly located in the third portion 32C of the interlayer dielectric layer 32. The dielectric layer 34 may be further disposed on the third portion 32C of the interlayer dielectric layer 32, another part of the dielectric layer 34 (such as a part of the second portion 34C of the dielectric layer 34) is sandwiched between two of the conductive lines M23 adjacent to each other, and a bottom surface BS63 of the dielectric layer 34 located on the third portion 32C of the interlayer dielectric layer 32 (such as the second portion 34C of the dielectric layer 34) is lower than the top surface TS52 of the second portion 32B of the interlayer dielectric layer 32 and higher than the bottom surface BS61 of the dielectric layer 34 located on the first portion 32A of the interlayer dielectric layer 32 (such as a first portion 34A of the dielectric layer 34) in the vertical direction D1. In some embodiments, a thickness of the dielectric layer 34 located on the third portion 32C of the interlayer dielectric layer 32 (such as the second portion 34C) is less than a thickness of the dielectric layer 34 located on the first portion 32A of the interlayer dielectric layer 32 (such as the first portion 34A).

In some embodiments, the third interconnection structure CS3 may further include a plurality of conductive lines M13 and at least one electrically conductive via structure V13. The conductive lines M13 may be disposed in the third portion 22C of the interlayer dielectric layer 22. The electrically conductive via structure V13 may be disposed between the conductive line M13 and the conductive line M23 for electrically connected the conductive line M13 and the conductive line M23, and the electrically conductive via structure V13 may be partly disposed in the third portion 32C of the interlayer dielectric layer 32 and penetrate through the third portion 26C of the dielectric layer 26 in the vertical direction D1. The conductive line and the electrically conductive via structure in the third interconnection structure CS3 may include a barrier layer and a low electrically resistance material disposed on the barrier layer, the low electrically resistance material may include a material with relatively low electrical resistivity, such as copper, aluminum, tungsten, and so forth, and the barrier layer may include titanium nitride, tantalum nitride, or other suitable barrier materials, but not limited thereto.

In some embodiments, the thicknesses of the first portion 22A, the second portion 22B, and the third portion 22C of the interlayer dielectric layer 22 may be substantially equal to one another, and the conductive lines M11, the conductive lines M12, and the conductive lines M13 may be formed concurrently by the same process and may be regarded as electrically conductive layers located at the same level. The bottom surface BS11 of each of the conductive lines M11, the bottom surface BS12 of each of the conductive lines M12, and a bottom surface BS13 of each of the conductive lines M13 may be substantially coplanar, and the top surface TS11 of each of the conductive lines M11, the top surface TS12 of each of the conductive lines M12, and a top surface TS13 of each of the conductive lines M13 may be substantially coplanar, but not limited thereto. In addition, the thicknesses of the first portion 26A, the second portion 26B, and the third portion 26C of the dielectric layer 26 may be substantially equal to one another, and a thickness of the third portion 32C of the interlayer dielectric layer 32 may be greater than the thickness of the first portion 32A of the interlayer dielectric layer 32 and less than the thickness of the second portion 32B of the interlayer dielectric layer 32. In some embodiments, the conductive lines M21, the conductive lines M22, and the conductive lines M23 may be formed concurrently by the same process and may be regarded as electrically conductive layers located at the same level. The bottom surface BS21 of each of the conductive lines M21, the bottom surface BS22 of each of the conductive lines M22, and a bottom surface BS23 of each of the conductive lines M23 may be substantially coplanar, and the top surface TS21 of each of the conductive lines M21, the top surface TS22 of each of the conductive lines M22, and a top surface TS23 of each of the conductive lines M23 may be substantially coplanar, but not limited thereto. In some embodiments, because of the influence of the planarization process, the top surface TS21 of the conductive line M21, the top surface TS61 of the first portion 34A of the dielectric layer 34, the top surface TS23 of the conductive line M23, a top surface TS63 of the second portion 34C of the dielectric layer 34, the top surface TS22 of the conductive line M22, and the top surface TS52 of the second portion 32B of the interlayer dielectric layer 32 may be substantially coplanar, but not limited thereto.

In some embodiments, the first device region R1 may be a high voltage device region and include a high voltage transistor device, the second device region R2 may be a low voltage device region and include a low voltage transistor device, and the third device region R3 may be a middle voltage device region and include a middle voltage transistor device. The first interconnection structure CS1, the second interconnection structure CS2, and the third interconnection structure CS3 may be interconnection structures disposed corresponding to and electrically connected with the high voltage transistor device, the low voltage transistor device, and the middle voltage transistor device, respectively. In other words, an operation voltage of the third device region R3 and the corresponding third interconnection structure CS3 may be higher than an operation voltage of the second device region R2 and the corresponding second interconnection structure CS2 and lower than an operation voltage of the first device region R1 and the corresponding first interconnection structure CS1. The dielectric layer 34 having relatively high dielectric constant and disposed between the conductive lines M23 adjacent to each other in the third interconnection structure CS3 may be used to improve the reliability of the dielectric material adjacent to the conductive lines M23. Because the operation voltage corresponding to the third interconnection structure CS3 is relatively low (lower than that of the first interconnection structure CS1), the thickness of the second portion 34C of the dielectric layer 34 located between the conductive lines M23 adjacent to each other may be less than the thickness of the first portion 34A of the dielectric layer 34 located between the conductive lines M21 adjacent to each other for reducing the negative influence on the capacitance effect and/or RC delay.

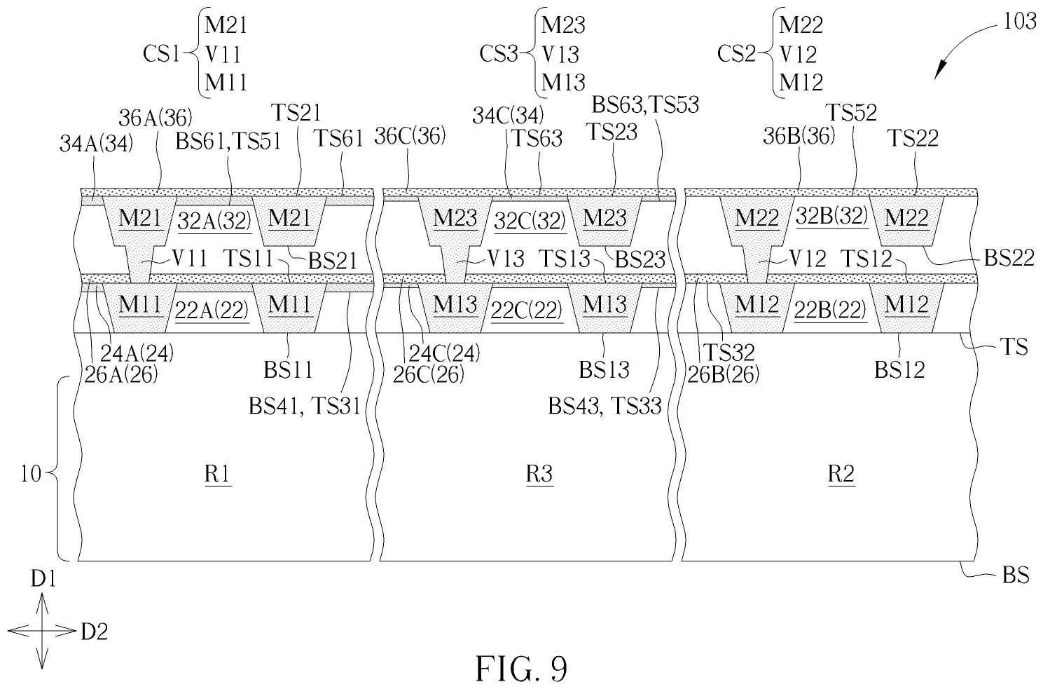

Please refer to FIG. 9. FIG. 9 is a schematic drawing illustrating a semiconductor device 103 according to a third embodiment of the present invention. As shown in FIG. 9, the semiconductor device 103 may further include a dielectric layer 24, and the dielectric layer 24 may include a first portion 24A and a second portion 24B located above the first device region R1 and the third device region R3, respectively. The first portion 24A of the dielectric layer 24 may be disposed between the first portion 22A of the interlayer dielectric layer 22 and the first portion 26A of the dielectric layer 26 in the vertical direction D1, and the first portion 24A of the dielectric layer 24 may be sandwiched between the conductive lines M11 adjacent to each other in the horizontal direction. The second portion 24C of the dielectric layer 24 may be disposed between the third portion 22C of the interlayer dielectric layer 22 and the third portion 26C of the dielectric layer 26 in the vertical direction D1, and the second portion 24C of the dielectric layer 24 may be sandwiched between the conductive lines M13 adjacent to each other in the horizontal direction. The dielectric layer 24 may include NDC, silicon nitride, silicon oxycarbide, silicon oxycarbonitride, or other suitable dielectric materials. In some embodiments, the material composition of the dielectric layer 24 may be identical to that of the dielectric layer 34 described above, and the thickness of the dielectric layer 24 may be equal to that of the dielectric layer 34, but not limited thereto. In other words, in some embodiments, the dielectric layer 24 and the dielectric layer 26 may be regarded as the first dielectric layer and the second dielectric layer described above, respectively, and the conductive line M11, the conductive line M12, and the conductive line M13 may be regarded as the first conductive line, the second conductive line, and the third dielectric layer described above, respectively, but not limited thereto.

In this situation, a top surface TS31 of the first portion 22A of the interlayer dielectric layer 22 may be lower than a top surface TS33 of the third portion 22C in the vertical direction D1, and the top surface TS22 of the third portion 22C may be lower than a top surface TS32 of the second portion 22B in the vertical direction D1. In addition, a bottom surface BS41 of the first portion 24A of the dielectric layer 24 may be lower than a bottom surface BS43 of the second portion 24C in the vertical direction D1, and the bottom surface BS43 of the second portion 24C may be lower than the top surface TS32 of the second portion 22B of the interlayer dielectric layer 22 in the vertical direction D1. The thickness of the first portion 24A of the dielectric layer 24 may be greater than the thickness of the second portion 24C of the dielectric layer 24, and the top surface TS11 of the conductive line M11, a top surface of the first portion 24A of the dielectric layer 24, the top surface TS13 of the conductive line M13, a top surface of the second portion 24C of the dielectric layer 24, the top surface TS12 of the conductive line M12, and the top surface TS32 of the second portion 22B of the interlayer dielectric layer 22 may be substantially coplanar, but not limited thereto.

In the present invention, the first dielectric layer having relatively high dielectric constant may be disposed above some of the device regions and located between adjacent conductive lines of specific patterned metallic electrically conductive layer. For example, in some embodiments, the conductive lines M11, the conductive lines M12, and the conductive lines M13 may be regarded as the first metal layer (the metal one layer) in the back end of line (BEOL) process of the semiconductor manufacturing process, and the conductive lines M21, the conductive lines M22, and the conductive lines M23 may be regarded as the second metal layer (the metal two layer) in the BEOL process. The dielectric layer having relatively high dielectric constant in this invention (such as the dielectric layer 24 and/or the dielectric layer 34) may be disposed in the interconnection structures located above the first device region R1 and the third device region R3 and sandwiched between adjacent conductive lines of each metal layer and/or adjacent conductive lines of a specific metal layer without being disposed above the second device region R2 for improving the reliability of the dielectric material located corresponding to the device region having relatively high operation voltage and reducing the negative influence of the dielectric layer having relatively high dielectric constant and disposed between the conductive lines of the interconnection structure located corresponding to the device region having relatively low operation voltage.

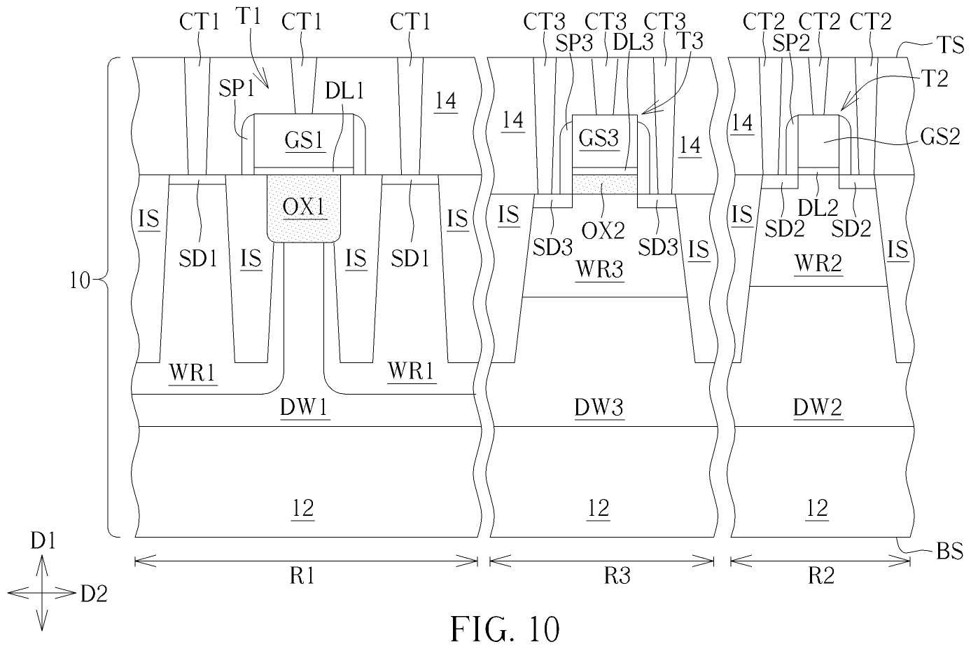

Please refer to FIG. 10. FIG. 10 is a schematic drawing illustrating the device layer in the semiconductor device according to an embodiment of the present invention. As shown in FIG. 10, in some embodiments, the device layer 10 may include a semiconductor substrate 12, an isolation structure IS, and a dielectric layer 14. The semiconductor substrate 12 may be located in the first device region R1, the second device region R2, and the third device region R3. The isolation structure IS may be disposed in the semiconductor substrate 12, and the dielectric layer 14 may be disposed on the semiconductor substrate 12 and located in the first device region R1, the second device region R2, and the third device region R3. In addition, the first device region R1, the second device region R2, and the third device region R3 may include a transistor T1, a transistor T2, and a transistor T3, respectively, and the operation voltages and/or the structures of the transistor T1, the transistor T2, and the transistor T3 may be different from one another. For example, the transistor T1, the transistor T2, and the transistor T3 may be regarded as a high voltage transistor structure, a low voltage transistor structure, and a middle voltage transistor structure, respectively, but not limited thereto. In some embodiments, the first device region R1 may include a deep well region DW1, well regions WR1, an oxide layer OX1, source/drain regions SD1, a gate dielectric layer DL1, a gate structure GS1, a spacer SP1, and contact structures CT1; the second device region R2 may include a deep well region DW2, a well region WR2, source/drain regions SD2, a gate dielectric layer DL2, a gate structure GS2, a spacer SP2, and contact structures CT2; and the third device region R3 may include a deep well region DW3, a well region WR3, an oxide layer OX2, source/drain regions SD3, a gate dielectric layer DL3, a gate structure GS3, a spacer SP3, and contact structures CT3.

The semiconductor substrate 12 may include a silicon substrate, a silicon germanium substrate, a silicon-on-insulator (SOI) substrate, or a semiconductor substrate made of other suitable materials. The isolation structure IS is disposed in the semiconductor substrate for providing isolation effects, and the isolation structure IS may include a single layer or multiple layers of insulation materials, such as silicon oxide, silicon nitride, or other suitable insulation materials. The deep well region DW1, the deep well region DW2, the deep well region DW3, the well region WR1, the well region WR2, the well region WR3, the source/drain region SD1, the source/drain region SD2, and the source/drain region SD3 may be doped regions formed in the semiconductor substrate 12 by doping processes (such as implantation processes), respectively, and the doping types of the doped region may be adjusted according to types of the corresponding transistor structures or other design considerations. The gate dielectric layer DL1, the gate dielectric layer DL2, and the gate dielectric layer DL3 may include high dielectric constant (high-k) dielectric materials or other suitable dielectric materials, and the gate structure GS1, the gate structure GS2, and the gate structure GS3 may include electrically conductive non-metallic materials (such as doped polysilicon) or electrically conductive metallic materials, such as a metal gate structure formed by stacking a work function layer and a low resistivity layer, but not limited thereto. The spacer SP1, the spacer SP2, and the spacer SP3 may respectively include a single layer or multiple layers of insulation materials, such as silicon oxide, silicon nitride, or other suitable insulation materials. The dielectric layer 14 may include a single layer or multiple layers of dielectric materials, such as silicon oxide, silicon nitride, or other suitable dielectric materials. The contact structure CT1, the contact structure CT2, and the contact structure CT3 may respectively include a barrier layer and a low electrically resistance material disposed on the barrier layer, the low electrically resistance material may include a material with relatively low electrical resistivity, such as copper, aluminum, tungsten, and so forth, and the barrier layer may include titanium nitride, tantalum nitride, or other suitable barrier materials, but not limited thereto.

In some embodiments, as shown in FIG. 9 and FIG. 10, the interconnection structures located corresponding to the device regions may be electrically connected with the gate structure and the source/drain structure in the corresponding transistor via the corresponding contact structures. For example, when the conductive line M11, the conductive line M12, and the conductive line M13 are the first metal layer in the BEOL process, the conductive line M11, the conductive line M12, and the conductive line M13 may directly contact and be electrically connected with the contact structure CT1, the contact structure CT2, and the contact structure CT3, respectively, but not limited thereto. In addition, the thickness of the gate oxide layer in the transistor structure may be modified for meeting the specific operation voltage of the transistor structure. For example, the thicker gate oxide layer may be used to enhance the ability of the transistor structure to withstand voltage, but not limited thereto. In some embodiments, the thickness of the oxide layer OX1 located under the gate structure GS1 in the first device region R1 may be greater than the thickness of the oxide layer OX2 located under the gate structure GS3 in the third device region R3, and there is not any gate oxide layer (except the gate dielectric layer DL2) disposed in the second device region R2 for realizing the design where the operation voltage of the transistor T1 is higher than that of the transistor T3 and the operation voltage of the transistor T3 is higher than that of the transistor T2. In addition, the thicker oxide layer OX1 and/or the thicker oxide layer OX2 may be at least partially disposed in the semiconductor substrate 12 for avoiding and/or reducing the negative influence of the oxide layer on other processes. It is worth noting that the device layer 10 illustrated in FIG. 10 may be applied in other embodiments of the present invention, such as the first embodiment, the second embodiment, and the third embodiment described above, and the first device region R1, the second device region R2, and the third device region R3 in the device layer 10 of the present invention may include but are not limited to the structure illustrated in FIG. 10.

To summarize the above descriptions, according to the semiconductor device and the manufacturing method thereof in the present invention, by the design where the top surface of the first portion of the interlayer dielectric layer is lower than the top surface of the second portion of the interlayer dielectric layer, the first dielectric layer may be disposed on the first portion of the interlayer dielectric layer without being disposed on the second portion of the interlayer dielectric layer for meeting the characteristic requirements of the interconnection structures located corresponding to different device regions and the dielectric materials adjacent to the interconnection structures. The overall reliability and/or the operation performance of the semiconductor device may be enhanced accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a device layer comprising a first device region and a second device region;
an interlayer dielectric layer disposed above the device layer, wherein the interlayer dielectric layer comprises:
a first portion disposed above the first device region; and
a second portion disposed above the second device region, wherein a top surface of the first portion is lower than a top surface of the second portion in a vertical direction;
a first interconnection structure disposed corresponding to the first device region, wherein the first interconnection structure comprises first conductive lines, and each of the first conductive lines is partly located in the first portion of the interlayer dielectric layer;
a second interconnection structure disposed corresponding to the second device region, wherein the second interconnection structure comprises second conductive lines located in the second portion of the interlayer dielectric layer; and
a first dielectric layer disposed on the first portion of the interlayer dielectric layer, wherein a part of the first dielectric layer is sandwiched between two of the first conductive lines adjacent to each other, and a bottom surface of the first dielectric layer is lower than the top surface of the second portion of the interlayer dielectric layer in the vertical direction.

2. The semiconductor device according to claim 1, wherein the bottom surface of the first dielectric layer and the top surface of the first portion of the interlayer dielectric layer are higher than a bottom surface of each of the first conductive lines and a bottom surface of each of the second conductive lines in the vertical direction, and the bottom surface of the first dielectric layer and the top surface of the first portion of the interlayer dielectric layer are lower than a top surface of each of the first conductive lines and a top surface of each of the second conductive lines in the vertical direction.

3. The semiconductor device according to claim 1, wherein a top surface of each of the first conductive lines and a top surface of each of the second conductive lines are coplanar.

4. The semiconductor device according to claim 1, wherein a top surface of each of the second conductive lines and the top surface of the second portion of the interlayer dielectric layer are coplanar.

5. The semiconductor device according to claim 1, wherein a dielectric constant of the first dielectric layer is higher than a dielectric constant of the interlayer dielectric layer.

6. The semiconductor device according to claim 1, further comprising:
a second dielectric layer disposed on and contacting each of the first conductive lines, the first dielectric layer, each of the second conductive lines, and the second portion of the interlayer dielectric layer, wherein a dielectric constant of the second dielectric layer is higher than a dielectric constant of the interlayer dielectric layer.

7. The semiconductor device according to claim 6, wherein a material composition of the second dielectric layer is identical to a material composition of the first dielectric layer.

8. The semiconductor device according to claim 6, wherein a dielectric constant of the first dielectric layer is higher than a dielectric constant of the second dielectric layer.

9. The semiconductor device according to claim 6, wherein a thickness of the first dielectric layer is greater than a thickness of the second dielectric layer.

10. The semiconductor device according to claim 1, wherein a dielectric constant of the first dielectric layer ranges from 4 to 6.

11. The semiconductor device according to claim 1, wherein the first device region is a high voltage device region, and the second device region is a low voltage device region.

12. The semiconductor device according to claim 1, wherein the device layer further comprises a third device region, the interlayer dielectric layer further comprises a third portion disposed above the third device region, and a top surface of the third portion is lower than the top surface of the second portion and higher than the top surface of the first portion in the vertical direction.

13. The semiconductor device according to claim 12, further comprising:
a third interconnection structure disposed corresponding to the third device region, wherein the third interconnection structure comprises third conductive lines, and each of the third conductive lines is partly located in the third portion of the interlayer dielectric layer, wherein the first dielectric layer is further disposed on the third portion of the interlayer dielectric layer, another part of the first dielectric layer is sandwiched between two of the third conductive lines adjacent to each other, and a bottom surface of the first dielectric layer located on the third portion of the interlayer dielectric layer is lower than the top surface of the second portion of the interlayer dielectric layer and higher than the bottom surface of the first dielectric layer located on the first portion of the interlayer dielectric layer in the vertical direction.

14. The semiconductor device according to claim 13, wherein a thickness of the first dielectric layer located on the third portion of the interlayer dielectric layer is less than a thickness of the first dielectric layer located on the first portion of the interlayer dielectric layer.

15. The semiconductor device according to claim 12, wherein the first device region is a high voltage device region, the second device region is a low voltage device region, and the third device region is a middle voltage device region.

16. A manufacturing method of a semiconductor device, comprising:
providing a device layer comprising a first device region and a second device region;
forming an interlayer dielectric layer above the device layer, wherein the interlayer dielectric layer comprises:
a first portion disposed above the first device region; and
a second portion disposed above the second device region, wherein a top surface of the first portion is lower than a top surface of the second portion in a vertical direction;
forming a first dielectric layer on the first portion of the interlayer dielectric layer;
forming first conductive lines, wherein each of the first conductive lines is partly located in the first portion of the interlayer dielectric layer, and the first conductive lines are a portion of a first interconnection structure located corresponding to the first device region; and
forming second conductive lines in the second portion of the interlayer dielectric layer, wherein the second conductive lines are a portion of a second interconnection structure located corresponding to the second device region, a part of the first dielectric layer is sandwiched between two of the first conductive lines adjacent to each other, and a bottom surface of the first dielectric layer is lower than the top surface of the second portion of the interlayer dielectric layer in the vertical direction.

17. The manufacturing method of the semiconductor device according to claim 16, wherein a method of forming the interlayer dielectric layer comprises:
forming an interlayer dielectric material above the device layer, wherein the interlayer dielectric material is partly located above the first device region and partly located above the second device region; and
performing an etching process to the interlayer dielectric material located above the first device region, wherein at least a part of the interlayer dielectric material located above the first device region is etched to be the first portion of the interlayer dielectric layer by the etching process, and the interlayer dielectric material located above the second device region becomes the second portion of the interlayer dielectric layer after the etching process.

18. The manufacturing method of the semiconductor device according to claim 16, wherein a method of forming the first dielectric layer comprises:
forming a dielectric material above the interlayer dielectric layer, wherein the dielectric material is partly located on the first portion of the interlayer dielectric layer and partly located on the second portion of the interlayer dielectric layer; and
performing a planarization process to the dielectric material, wherein the dielectric material located on the second portion of the interlayer dielectric layer is removed by the planarization process, and the dielectric material remaining on the first portion of the interlayer dielectric layer after the planarization process becomes the first dielectric layer.

19. The manufacturing method of the semiconductor device according to claim 16, wherein the first conductive lines and the second conductive lines are formed concurrently by the same process.

20. The manufacturing method of the semiconductor device according to claim 16, further comprising:
forming a second dielectric layer on the first conductive lines, the first dielectric layer, the second conductive lines, and the second portion of the interlayer dielectric layer, wherein a dielectric constant of the second dielectric layer is higher than a dielectric constant of the interlayer dielectric layer.
